(19) United States
(12) Patent Application Publication
(10) Pub. No.: US 2025/0056756 A1
(43) Pub. Date: Feb. 13, 2025

(54) Fan Device

(71) Applicant: Purple Cloud Development Pte. Ltd., Singapore (SG)

(72) Inventor: Shiman Xu, Singapore (SG)

(21) Appl. No.: 18/795,210

(22) Filed: Aug. 6, 2024

(30) Foreign Application Priority Data
Aug. 8, 2023 (CN) 202310992948.9

(51) Int. Cl. H05K 7/20; C08K 7/14; F04D 25/06; F04D 29/34

(52) U.S. Cl. CPC H05K 7/20172; C08K 7/14; F04D 25/0613; F04D 29/34

(57) ABSTRACT

A fan device may include a fan frame, fan assembly, and plurality of mount component assemblies. The fan assembly is rotatably disposed in the fan frame. Each plurality of mount component assemblies includes a fixing assembly, and mount assembly. The fixing assembly is disposed on the fan frame. The mount assembly includes a mount component, and bracket. The bracket is fixed to the mount component. The bracket includes a material having a second hardness and the mount component includes a material having a third hardness. The second hardness is greater than the third hardness. The mount assembly is fixedly locked to the fixing assembly via the bracket, driven by a pushing force.

### RELATED APPLICATIONS

This US application claims the benefit of priority to China application no. 202310992948.9, filed on Aug. 8, 2023, of which is incorporated herein by reference in its entirety.

### TECHNICAL FIELD

The present disclosure relates to heat-transfer components and assemblies, and more particularly, but not limited to, fan devices.

### BACKGROUND OF THE INVENTION

With increasing processing speed and performance of electronic devices, the amount of heat generated during operation of an electronic device has increased. The heat generation increases the temperature of the electronic device and, if the heat cannot be dissipated effectively, the reliability and performance of the electronic device is reduced. To prevent overheating of an electronic device, cooling apparatuses such as fans are used to efficiently dissipate the heat generated by the electronic device and, thereby ensure the standard operation of the electronic device.

In the case of fans or other rotating cooling devices, the fans may be assembled to a fan rack, chassis, radiator or bracket using fasteners. Fan power cables are attached to the fans for driving of the fans. However, as fan speeds increase, vibration of the fans increases. As vibration increases, misalignment may occur, causing vibration noises to increase and fasteners to loosen. Also, with increased vibration, poor connection between the power cables and the fan may lead to the fans to stop rotating. Moreover, fans generally have many parts, making assembly time-consuming and the risk of lost parts greater, and maintenance, repair, and parts replacement inconvenient and inefficient.

### SUMMARY OF THE INVENTION

The present disclosure provides a fan device with decreased parts, simplified assembly, and increased fan mounting elements for decreased vibration.

In some aspects, the techniques described herein relate to a fan device. The fan device may include a fan frame, a fan assembly, and a plurality of mount component assemblies. The fan assembly is rotatably disposed in the fan frame. Each plurality of mount component assemblies includes a fixing assembly and a mount assembly. The fixing assembly is disposed on the fan frame. The mount assembly includes a mount component and a bracket. The bracket is fixed to the mount component. The mount assembly is fixedly locked to the fixing assembly via the bracket.

In some aspects, the techniques described herein relate to a fan device, wherein the bracket includes a material having a second hardness and the mount component includes a material having a third hardness. The second hardness is greater than the third hardness.

In some aspects, the techniques described herein relate to a fan device, wherein the material having the third hardness includes at least one of a silica gel material, a thermoplastic polyurethane (TPU) material, or a thermoplastic vulcanizate (TPV) material, or any combination of the foregoing.

In some aspects, the techniques described herein relate to a fan device, wherein the material having the second hardness includes at least one of a polybutylene terephthalate material, a polycarbonate material, a polyamide material, a liquid crystal polymer (LCP) material, a polyphenylene sulfide (PPS) material, a glass fiber reinforced polybutylene terephthalate material, a glass fiber reinforced polycarbonate material, a glass fiber reinforced polyamide material, a glass fiber reinforced liquid crystal polymer material, or a glass fiber reinforced polyphenylene sulfide material or any combination of the foregoing.

In some aspects, the techniques described herein relate to a fan device, wherein the fan frame includes a material including glass fiber reinforced polybutylene terephthalate.

In some aspects, the techniques described herein relate to a fan device, wherein the mount component includes a cavity bracket housing and pair of fixing members. Each pair of fixing members is disposed perpendicularly protruding from the cavity bracket housing at opposing perimeter ends of the cavity bracket housing. Each pair of fixing members includes a through hole. The through hole is configured for a fastener to be inserted through the through hole for fastening of the fan device.

In some aspects, the techniques described herein relate to a fan device, wherein the bracket includes a bracket frame and a pair of secondary fixing members. Each pair of secondary fixing members is disposed perpendicularly protruding from the bracket frame at opposing perimeter ends of the bracket frame. Each pair of fixing members includes a fixing through hole. The fixing through hole is aligned with the through hole.

In some aspects, the techniques described herein relate to a fan device, wherein the fan frame includes a plurality of transmission contact areas. Each bracket frame abuts the fan frame at the plurality of transmission contact areas.

In some aspects, the techniques described herein relate to a fan device, wherein the bracket frame includes a pair of first pegs, a pair of second pegs, and a pair of peg base members. Each pair of first pegs and each pair of second pegs are respectively disposed perpendicularly protruding from each pair of peg base members at opposing perimeter ends of each pair of peg base members. The cavity bracket housing includes a pair of secondary fixing member cut outs, a pair of first peg cut outs, and a pair of second peg cut outs. Each pair of secondary fixing members correspond to and abut each pair of secondary fixing member cut outs. Each pair of first pegs correspond to and abut each pair of first peg cut outs. Each pair of second pegs correspond to and abut each pair of second peg cut outs.

In some aspects, the techniques described herein relate to a fan device, wherein the bracket frame further includes a pair of first retaining members and a pair of second retaining members. Each pair of first retaining members are respectively disposed perpendicularly protruding from perimeter ends of each pair of first pegs. Each pair of second retaining members are respectively disposed perpendicularly protruding from perimeter ends of each pair of second pegs. Each pair of first pegs and respective perimeter ends of each pair of peg base members define a pair of first deflection parts. Each pair of second pegs and respective perimeter ends of each pair of peg base members define a pair of second deflection parts. The mount assembly is fixedly locked to the fixing assembly via the pair of first retaining members and the pair of second retaining members.

In some aspects, the techniques described herein relate to a fan device, wherein the fixing assembly includes a pair of first guide base members and a pair of second guide base members. Each pair of first guide base members is respectively disposed longitudinally connected to each pair of second guide base members. Each pair of first guide base members include a first end and a first guide protrusion. The first guide protrusion is disposed perpendicularly protruding from the first end. Each pair of second guide base members include a second end and a second guide protrusion. The second guide protrusion is disposed perpendicularly protruding from the second end. When the mount assembly is fixedly locked to the fixing assembly, each pair of first retaining members and each pair of second retaining members are respectively disposed abutting each pair of first guide base members and each pair of second guide base members, and each first guide protrusion and each second guide protrusion are respectively disposed abutting each pair of first deflection parts and each pair of second deflection parts.

In some aspects, the techniques described herein relate to a fan device, wherein the mount assembly is fixedly locked to the fixing assembly via a pushing force.

In some aspects, the techniques described herein relate to a fan device, wherein the fan frame includes a motor, and wherein the fan assembly includes a hub and a plurality of blades. The plurality of blades radially extend from the hub and the motor receives power to drive the fan assembly.

In some aspects, the techniques described herein relate to a fan device, wherein the plurality of mount component assemblies includes four plurality of mount component assemblies. Each plurality of mount component assemblies is disposed on opposing corners of the fan frame.

### BRIEF DESCRIPTION OF DRAWINGS

Unless specified otherwise, the accompanying drawings illustrate aspects of the innovative subject matter described herein. Referring to the drawings, wherein like reference numerals indicate similar parts throughout the several views, several examples of fan devices incorporating aspects of the presently disclosed principles are illustrated by way of example, and not by way of limitation.

FIG. 1A illustrates a perspective view of a fan device, in accordance with various embodiments of the present disclosure.

FIG. 1B illustrates another perspective view of the fan device of FIG. 1A, in accordance with various embodiments of the present disclosure.

FIG. 1C illustrates an exploded view of the fan device of FIG. 1A, in accordance with various embodiments of the present disclosure.

FIG. 1D illustrates another exploded view of the fan device of FIG. 1A, in accordance with

various embodiments of the present disclosure.

FIG. 2 illustrates a perspective view of a bracket frame of a bracket of a mount assembly fixedly locked to a fixing assembly of the fan device of FIG. 1A, in accordance with various embodiments of the present disclosure.

FIG. 3 illustrates a cross-section view of a mount assembly fixedly locked to a fixing assembly of the fan device of FIG. 1A, in accordance with various embodiments of the present disclosure.

FIG. 4 illustrates another cross-section view of a mount assembly fixedly locked to a fixing assembly of the fan device of FIG. 1A, in accordance with various embodiments of the present disclosure.

### DETAILED DESCRIPTION

The following describes various principles related to components and assemblies for electronic devices cooling by way of reference to specific examples of fan devices, including specific arrangements and examples of mount component assemblies embodying innovative concepts. More particularly, but not exclusively, such innovative principles are described in relation to selected examples of brackets of mount assemblies fixed to mount components of mount assemblies and retaining members locking the mount assemblies to fixing assemblies disposed on fan frames, and well-known functions or constructions are not described in detail for purposes of succinctness and clarity. Nonetheless, one or more of the disclosed principles can be incorporated in various other embodiments of brackets fixed to mount components and retaining members locking mount assemblies to fixing assemblies to achieve any of a variety of desired outcomes, characteristics, and/or performance criteria.

Thus, fan devices having attributes that are different from those specific examples discussed herein can embody one or more of the innovative principles, and can be used in applications not described herein in detail. Accordingly, embodiments of fan devices not described herein in detail also fall within the scope of this disclosure, as will be appreciated by those of ordinary skill in the relevant art following a review of this disclosure.

Example embodiments as disclosed herein are directed to fan devices that can be used in cooling systems to dissipate high heat loads. The cooling system may be configured on a chassis, within a chassis, or as part of an electronics system that includes heat producing electronic components to be cooled. The cooling system includes at least one fan device. The fan device may be coupled to the chassis via a fastener (e.g., bolts, screws, etc.), transporting air to heat producing electronic components to be cooled and/or to an outside of the chassis or electronics system. The cooling system may further comprise one or more liquid-based cooling loops. The fan devices may be coupled to the back end of a radiator via a fastener at structural portions of the radiator, transporting air through the radiator to an air plenum or to the outside of the chassis or electronics system.

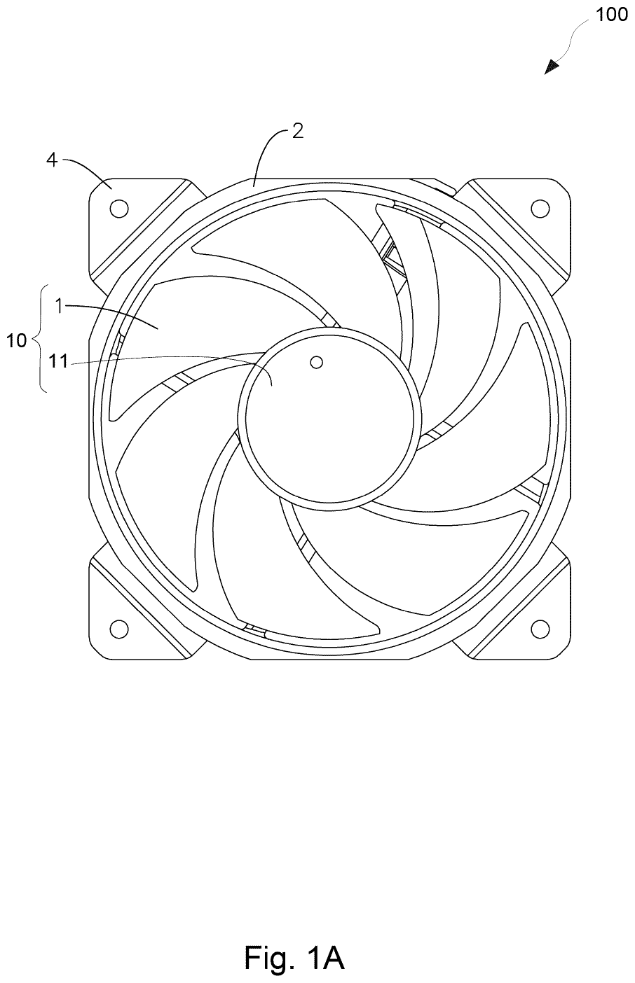

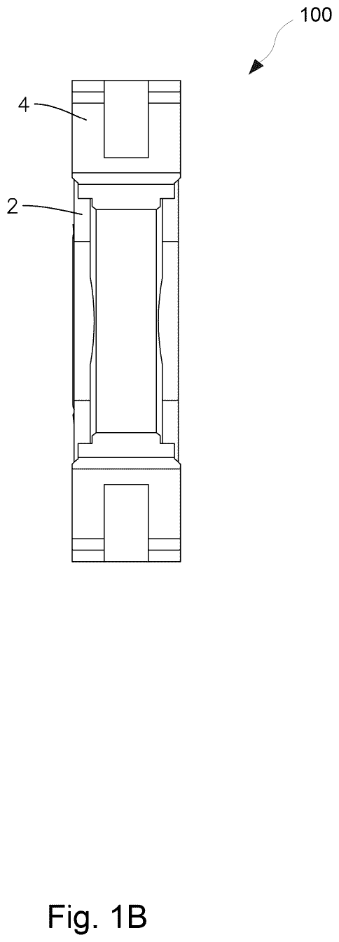

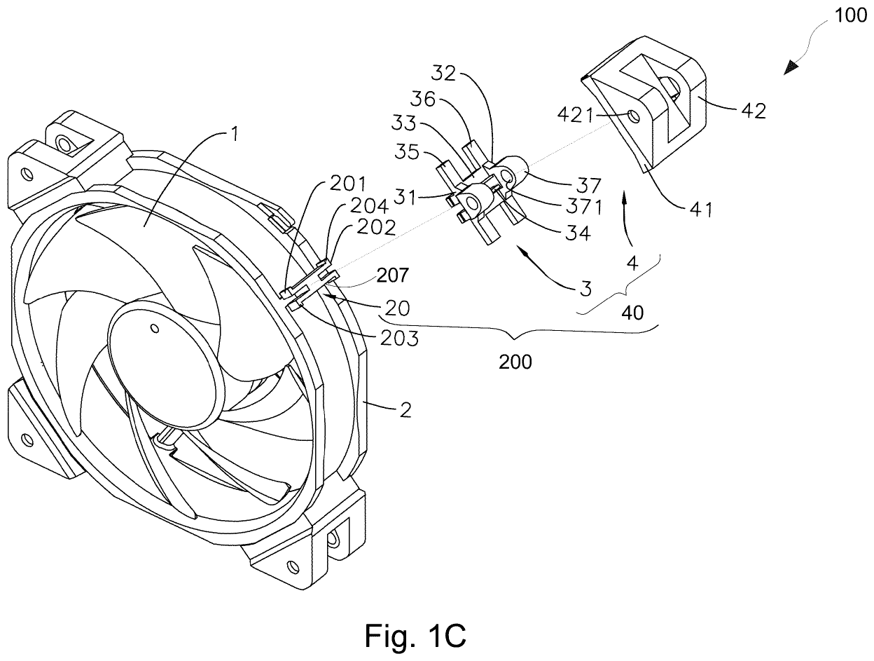

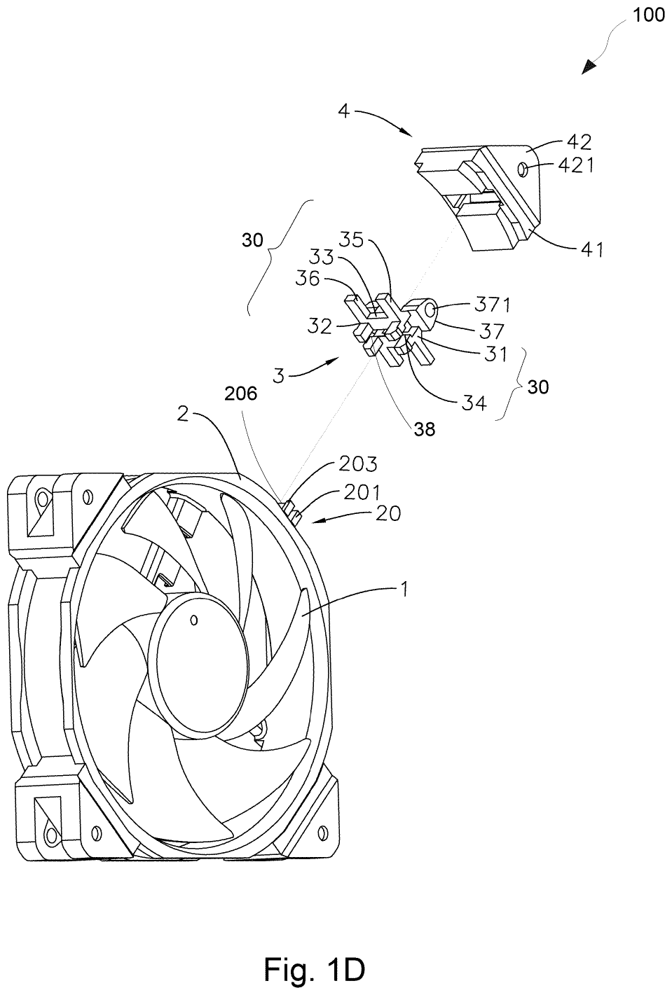

FIGS. 1A to 1D illustrate a fan device 100, in accordance with various embodiments of the present disclosure. The fan device 100 may include a fan frame 2, a fan assembly 10, and a plurality of mount component assemblies 200. The fan assembly 10 is rotatably disposed in the fan frame 2. Each plurality of mount component assemblies 200 includes a fixing assembly 20 and a mount assembly 40. The fixing assembly 20 is disposed laterally on an outer side of the fan frame 2 opposite the fan assembly 10. The mount assembly 40 includes a mount component 4 and a bracket 3. The bracket 3 is fixed to the mount component 4. The mount assembly 40 is fixedly locked to the fixing assembly 20 via the bracket 3.

In some embodiments, the fan frame 2 includes a motor, and the fan assembly 10 includes a hub 11 and a plurality of blades 1. The plurality of blades 1 radially extend from the hub 11 and the motor receives power to drive the fan assembly 10.

In some embodiments, the mount component 4 includes a cavity bracket housing 41 and pair of fixing members 42. Each pair of fixing members 42 is disposed perpendicularly protruding from the cavity bracket housing 41 at opposing perimeter ends of the cavity bracket housing 41 and can be triangular-like shaped. Each pair of fixing members 42 includes a through hole 421. The through hole 421 is configured for a fastener (not shown) to be inserted through the through hole 421 for fastening of the fan device 100.

In some embodiments, the bracket 3 includes a bracket frame 30 and a pair of secondary fixing members 37. Each pair of secondary fixing members 37 is disposed perpendicularly protruding from the bracket frame 30 at opposing perimeter ends of the bracket frame 30 and can be semi-circular shaped. Each pair of fixing members 42 includes a fixing through hole 371. The fixing through hole 371 is aligned with the through hole 421.

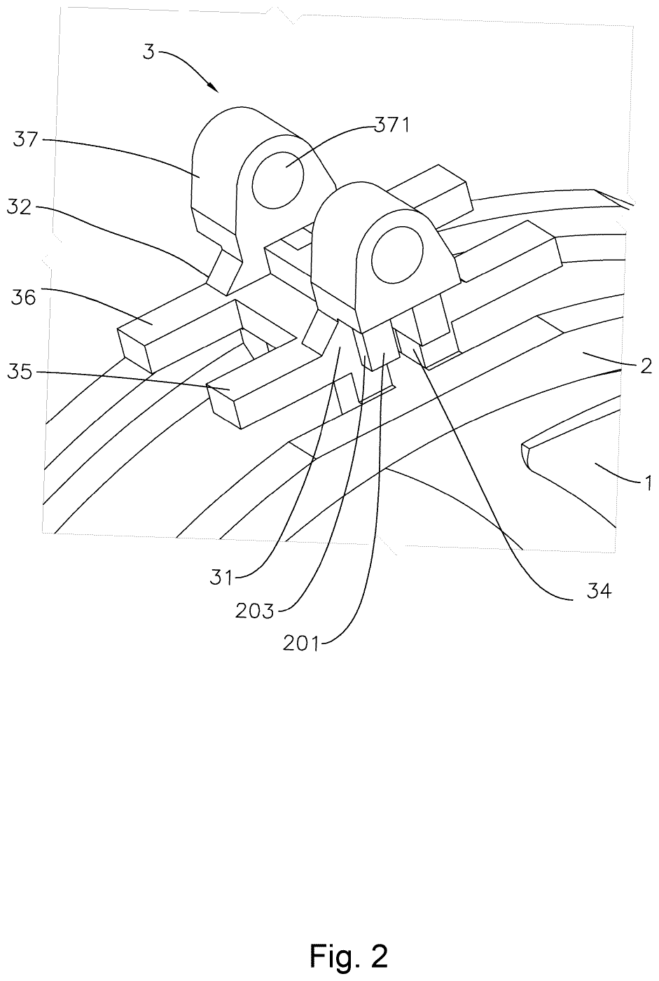

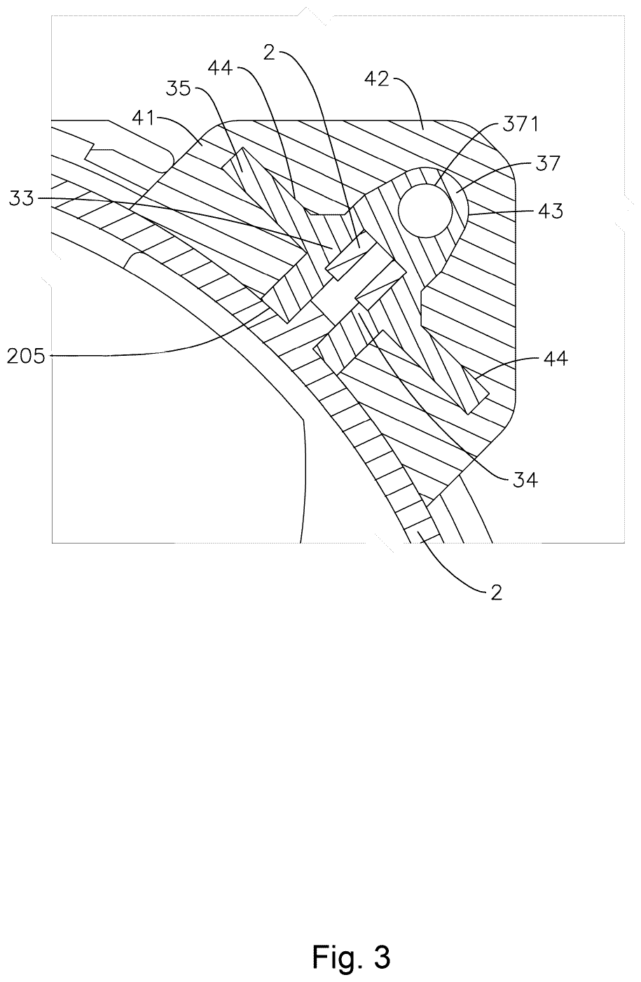

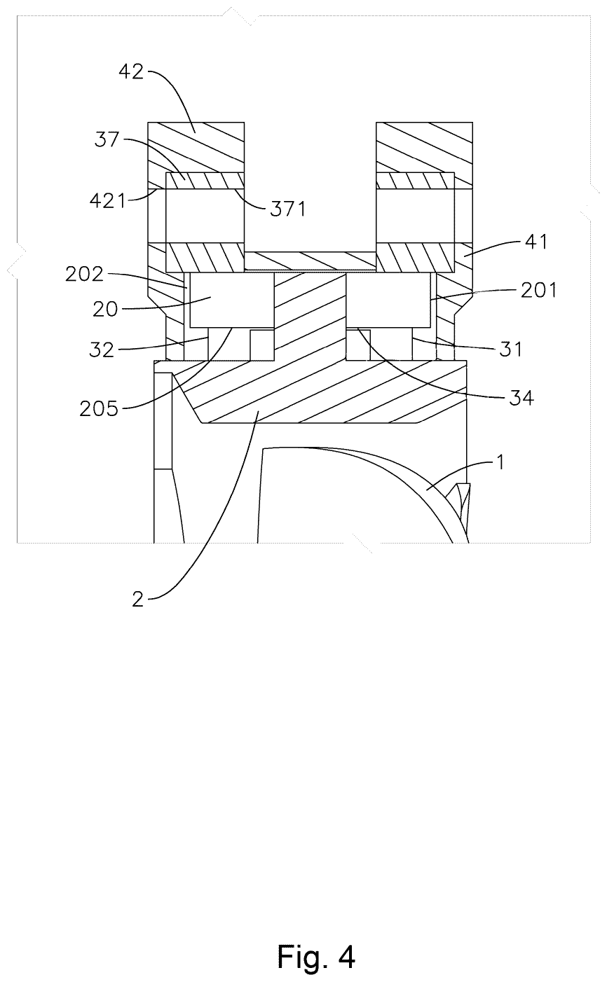

FIGS. 2 to 4 illustrate a mount assembly 40 fixedly locked to a fixing assembly 20 of the fan device 100, in accordance with various embodiments of the present disclosure. The bracket frame 30 includes a pair of first pegs 35, a pair of second pegs 36, and a pair of peg base members 33. Each pair of first pegs 35 and each pair of second pegs 36 are respectively disposed perpendicularly protruding from each pair of peg base members 33 at opposing perimeter ends of each pair of peg base members 33. Each of the pair of first pegs 35, the pair of second pegs 36, and the pair of peg base members 33 can respectively be rectangular-shaped, whereby one of each of the pair of first pegs 35, the pair of second pegs 36, and the pair of peg base members 33 can form a third side U-like shaped member, and the other of the pair of first pegs 35, the pair of second pegs 36, and the pair of peg base members 33 and form a fourth side U-like shaped member. The third side U-liked shaped member is separate from the fourth side U-liked shaped member. The cavity bracket housing 41 includes a pair of secondary fixing member cut outs 43, a pair of first peg cut outs, and a pair of second peg cut outs. Each pair of secondary fixing members 37 correspond to and abut each pair of secondary fixing member cut outs 43. Each pair of first pegs 35 correspond to and abut each pair of first peg cut outs. Each pair of second pegs 36 correspond to and abut each pair of second peg cut outs.

In some embodiments, the bracket frame 30 further includes a pair of first retaining members 34 and a pair of second retaining members 38. Each pair of first retaining members 34 are respectively disposed perpendicularly protruding from perimeter ends of each pair of first pegs 35. Each pair of second retaining members 38 are respectively disposed perpendicularly protruding from perimeter ends of each pair of second pegs 36. Each pair of first retaining members 34 and each pair of second retaining members 38 can respectively be hook-type shaped. Each pair of first pegs 35 and respective perimeter ends of each pair of peg base members 33 define a pair of first deflection parts 31. Each pair of second pegs 36 and respective perimeter ends of each pair of peg base members 33 define a pair of second deflection parts 32. The pair of first deflection parts 31 and the pair of second deflection parts 32 are deformable. The mount assembly 40 is fixedly locked to the fixing assembly 20 via the pair of first retaining members 34 and the pair of second retaining members 38.

In some embodiments, the fixing assembly 20 includes a pair of first guide base members 206 and a pair of second guide base members 207. Each pair of first guide base members 206 is respectively disposed longitudinally connected to each pair of second guide base members 207. The pair of first guide base members 206 and the pair of second guide base members 207 can form an H-like shaped member. Each pair of first guide base members 206 include a first end 201 and a first guide protrusion 203. The first guide protrusion 203 is disposed perpendicularly protruding from the first end 201. Each pair of second guide base members 207 include a second end 202 and a second guide protrusion 204. The second guide protrusion 204 is disposed perpendicularly protruding from the second end 202. When the mount assembly 40 is fixedly locked to the fixing assembly 20, each pair of first retaining members 34 and each pair of second retaining members 38 are respectively disposed abutting each pair of first guide base members 206 and each pair of second guide base members 207, and each first guide protrusion 203 and each second guide protrusion 204 are respectively disposed abutting each pair of first deflection parts 31 and each pair of second deflection parts 32.

In some embodiments, the fan frame 2 includes a plurality of transmission contact areas 205. Each bracket frame 30 abuts the fan frame 2 at the plurality of transmission contact areas 205. In some embodiments, the mount assembly 40 is fixedly locked to the fixing assembly 20 via a pushing force.

When the mount assembly 40 is being fixedly locked to the fixing assembly 20, the mount assembly 40 is pushed toward the fixing assembly 20. Each first guide protrusion 203 and each second guide protrusion 204 respectively guide ends of the pair of first retaining members 34 and the pair of second retaining members 38 toward the plurality of transmission contact areas 205 to contact and abut the plurality of transmission contact areas 205. At the same time, each pair of first deflection parts 31 and each pair of second deflection parts 32 are respectively deformed by each pair of first guide base members 206 and each pair of second guide base members 207 before snapping back and returning to original shapes, whereby each pair of first retaining members 34 and each pair of second retaining members 38 are respectively disposed abutting each pair of first guide base members 206 and each pair of second guide base members 207, fixedly locking the mount assembly 40 to the fixing assembly 20.

In some embodiments, the mount assembly 40 is unlocked from the fixing assembly 20 via bending of at least one side of the mount assembly 40 in a direction perpendicularly away from the fixing assembly 20 and fan frame 2.

In some embodiments, the plurality of mount component assemblies 200 includes four plurality of mount component assemblies 200. Each plurality of mount component assemblies 200 is disposed on opposing corners of the fan frame 2.

In some embodiments, the bracket 3 includes a material having a second hardness and the mount component 4 includes a material having a third hardness. The second hardness is greater than the third hardness.

In some embodiments, the material having the third hardness can be a soft thermoplastic and includes at least one of a silica gel material, a thermoplastic polyurethane (TPU) material, or a thermoplastic vulcanizate (TPV) material, or any combination of the foregoing. The material having the third hardness can be a thermoplastic polyurethane (TPU) material having a density of 1.10 g/cm3 to 1.25 g/cm3, inclusive.

In some embodiments, the material having the second hardness can be a hard thermoplastic material and includes at least one of a polybutylene terephthalate material, a polycarbonate material, a polyamide material, a liquid crystal polymer (LCP) material, a polyphenylene sulfide (PPS) material, a glass fiber reinforced polybutylene terephthalate material, a glass fiber reinforced polycarbonate material, a glass fiber reinforced polyamide material, a glass fiber reinforced liquid crystal polymer material, or a glass fiber reinforced polyphenylene sulfide material or any combination of the foregoing. The material having the second hardness can be a polycarbonate material having a density of 1.18 g/cm3 to 1.22 g/cm3, inclusive.

In some embodiments, the fan frame 2 includes a material including glass fiber reinforced polybutylene terephthalate. The glass fiber reinforced polybutylene terephthalate can be a 30% glass fiber reinforced polybutylene terephthalate. The glass fiber reinforced polybutylene terephthalate can be a 30% or less % glass fiber reinforced polybutylene terephthalate. The glass fiber reinforced polybutylene terephthalate can have a density of 1.3 g/cm3 to 1.6 g/cm3, inclusive.

Generally, glass fiber reinforced polybutylene terephthalate materials have mechanical properties of high tensile, moduli, flexural, and compressive strengths. The mechanical properties of the fan frame 2 are configured for the fan device 100 to operate stably at high fan speeds (RPMs or rotations per minute). Generally, polycarbonate materials have mechanical properties of being strong, stiff, hard, tough, and impact resistance. The mechanical properties of the bracket 3 are configured to reduce vibration and noise via transmission of mechanical vibrations of the fan frame 2 to the bracket 3. Generally, thermoplastic polyurethane (TPU) materials have mechanical properties of durability, flexibility, and high tensile strength. The mechanical properties of the bracket 3 are configured to absorb shocks and vibrations.

Simplified and multi-material mount assemblies provide efficient vibration transmission and assembly of the fan devices 100 of the embodiments. The first guide protrusion 203 and the second guide protrusion 204, guide ends of the pair of first retaining members 34 and the pair of second retaining members 38 to contact and abut the plurality of transmission contact areas 205 and allow the pair of first retaining members 34 and the pair of second retaining members 38 to snap back and abut the pair of first guide base members 206 and the pair of second guide base members 207. The pair of first retaining members 34 and the pair of second retaining members 38 are locked to the pair of first guide base members 206 and the pair of second guide base members 207 preventing the mount assembly 40 from moving laterally away from the fixing assembly 20 and fan frame 2. The pair of first guide protrusions 203 and the pair of second guide protrusions 204 additionally prevents the mount assembly 40 from moving upward or downward along the fixing assembly 20 and fan frame 2. Bending one side of the mount assembly 40 in a direction perpendicularly away from the fixing assembly 20 and fan frame 2 efficiently releases the mount assembly 40 from the fixing assembly 20. Thus, maintenance, repair, and replacement of the mount assembly 40 is convenient and efficient. Vibration of the fan device 100 is decreased via vibration transmission from the fan assembly 10 to the fan frame 2 and then to the fixing assembly 20 and mount assembly 40 via the bracket 3 and the mount component 4. The fan frame 2 transmits vibrations to the fixing assembly 20 for a first pathway of initial reduction of vibrations. The plurality of transmission contact areas 205 directly transmit vibrations from the fan frame 2 to the ends of the pair of first retaining members 34 and the pair of second retaining members 38 for a second pathway of initial reduction of vibrations, increasing the area of the initial reduction of vibrations and enhancing the initial reduction of vibrations. The vibrations are absorbed by the bracket frame 30 in contact with and locked to the fixing assembly 20 for a combined pathway, further reducing vibrations. The vibrations are then transmitted from the bracket frame 30 to the mount component 4 for a final pathway of reduced vibrations. Thus, vibrations occurring at the fasteners via the through hole 421 and fixing through hole 371 is decreased via the first and second pathways, the combined pathway, and the final pathway of reduction of vibrations. Furthermore, the material of the bracket 3 having the second hardness, being greater than the material of the mount component 4 having the third hardness, even further enhances transmission of vibrations and the decrease in vibrations of the fan devices 100.

Therefore, embodiments disclosed herein are well adapted to attain the ends and advantages mentioned as well as those that are inherent therein. The particular embodiments disclosed above are illustrative only, as the embodiments disclosed may be modified and practiced in different but equivalent manners apparent to those of ordinary skill in the relevant art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure. The embodiments illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some number. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the elements that it introduces.

1. A fan device, comprising:
a fan frame;
a fan assembly rotatably disposed in the fan frame; and
a plurality of mount component assemblies, each plurality of mount component assemblies includes a fixing assembly and a mount assembly, the mount assembly comprising a mount component and a bracket, the bracket fixed to the mount component, the fixing assembly disposed on the fan frame, the mount assembly fixedly locked to the fixing assembly via the bracket.

2. The fan device of claim 1, wherein the bracket includes a material having a second hardness and the mount component includes a material having a third hardness, wherein the second hardness is greater than the third hardness.

3. The fan device of claim 2, wherein the material having the third hardness comprises at least one of a silica gel material, a thermoplastic polyurethane (TPU) material, or a thermoplastic vulcanizate (TPV) material, or any combination of the foregoing.

4. The fan device of claim 2, wherein the material having the second hardness comprises at least one of a polybutylene terephthalate material, a polycarbonate material, a polyamide material, a liquid crystal polymer (LCP) material, a polyphenylene sulfide (PPS) material, a glass fiber reinforced polybutylene terephthalate material, a glass fiber reinforced polycarbonate material, a glass fiber reinforced polyamide material, a glass fiber reinforced liquid crystal polymer material, or a glass fiber reinforced polyphenylene sulfide material or any combination of the foregoing.

5. The fan device of claim 1, wherein the fan frame includes a material comprising glass fiber reinforced polybutylene terephthalate.

6. The fan device of claim 1, wherein the mount component comprises a cavity bracket housing and pair of fixing members, each pair of fixing members disposed perpendicularly protruding from the cavity bracket housing at opposing perimeter ends of the cavity bracket housing, each pair of fixing members includes a through hole, the through hole configured for a fastener to be inserted through the through hole for fastening of the fan device.

7. The fan device of claim 6, wherein the bracket comprises a bracket frame and a pair of secondary fixing members, each pair of secondary fixing members disposed perpendicularly protruding from the bracket frame at opposing perimeter ends of the bracket frame, each pair of fixing members including a fixing through hole, the fixing through hole aligned with the through hole.

8. The fan device of claim 7, wherein the fan frame comprises a plurality of transmission contact areas, each bracket frame abuts the fan frame at the plurality of transmission contact areas.

9. The fan device of claim 7, wherein the bracket frame comprises a pair of first pegs, a pair of second pegs, and a pair of peg base members, each pair of first pegs and each pair of second pegs respectively disposed perpendicularly protruding from each pair of peg base members at opposing perimeter ends of each pair of peg base members, and wherein the cavity bracket housing comprises a pair of secondary fixing member cut outs, a pair of first peg cut outs, and a pair of second peg cut outs, each pair of secondary fixing members corresponding to and abutting each pair of secondary fixing member cut outs, each pair of first pegs corresponding to and abutting each pair of first peg cut outs, each pair of second pegs corresponding to and abutting each pair of second peg cut outs.

10. The fan device of claim 9, wherein the bracket frame further comprises a pair of first retaining members and a pair of second retaining members, each pair of first retaining members respectively disposed perpendicularly protruding from perimeter ends of each pair of first pegs, each pair of second retaining members respectively disposed perpendicularly protruding from perimeter ends of each pair of second pegs, and wherein each pair of first pegs and respective perimeter ends of each pair of peg base members define a pair of first deflection parts, and each pair of second pegs and respective perimeter ends of each pair of peg base members define a pair of second deflection parts, the mount assembly fixedly locked to the fixing assembly via the pair of first retaining members and the pair of second retaining members.

11. The fan device of claim 10, wherein the fixing assembly comprises a pair of first guide base members and a pair of second guide base members, each pair of first guide base members respectively disposed longitudinally connected to each pair of second guide base members, each pair of first guide base members include a first end and a first guide protrusion, the first guide protrusion disposed perpendicularly protruding from the first end, each pair of second guide base members include a second end and a second guide protrusion, the second guide protrusion disposed perpendicularly protruding from the second end, when the mount assembly is fixedly locked to the fixing assembly, each pair of first retaining members and each pair of second retaining members are respectively disposed abutting each pair of first guide base members and each pair of second guide base members, and each first guide protrusion and each second guide protrusion are respectively disposed abutting each pair of first deflection parts and each pair of second deflection parts.

12. The fan device of claim 1, wherein the mount assembly is fixedly locked to the fixing assembly via a pushing force.

13. The fan device of claim 1, wherein the fan frame comprises a motor, and wherein the fan assembly comprises a hub and a plurality of blades, the plurality of blades radially extending from the hub, the motor receiving power to drive the fan assembly.

14. The fan device of claim 1, wherein the plurality of mount component assemblies comprises four plurality of mount component assemblies, each plurality of mount component assemblies disposed on opposing corners of the fan frame.
